(19) United States
(12) Patent Application Publication
(10) Pub. No.: US 2011/0225476 A1
(43) Pub. Date: Sep. 15, 2011

(54) System And Method For Enabling A Buffer Less Or Substantially Buffer Less Core Network

(76) Inventors: Marina K. Thottan, Westfield, NJ (US); Vijay Sivaraman, Gladesville (AU); Konstantinos Dovrolis, Atlanta, GA (US); Arun Vishwanath, Sydney (AU)

(21) Appl. No.: 13/042,730

(22) Filed: Mar. 8, 2011

Related U.S. Application Data
(60) Provisional application No. 61/313,279, filed on Mar. 12, 2010.

(51) Int. Cl. H03M 13/05; G06F 11/10

(52) U.S. Cl. 714/776; 714/E11.032

(57) ABSTRACT

The present invention relates to a system and method for enabling a buffer-less or substantially buffer-less core network using a packet-level forward error correction (FEC) coding scheme. The system includes an ingress edge router configured to receive data packets destined to at least one egress edge router via an access link from an end-host. The ingress edge router is connected to the at least one egress edge router via a core network, where the core network is buffer-less or substantially buffer-less. Also, the ingress edge router is configured to apply a forward error correction (FEC) encoding scheme to the data packets at a packet level and transmit the encoded data packets to the core network.

### PRIORITY INFORMATION

This U.S. non-provisional patent application claims priority under 35 U.S.C. §119 of U.S. provisional patent application No. 61/313,279, filed on Mar. 12, 2010, the entire contents of which are incorporated herein by reference.

### ACKNOWLEDGEMENT OF GOVERNMENT SUPPORT

This invention was made under Government Contract Number FA8750-04-C-0013 awarded by the Defense Advanced Research Projects Agency (DARPA). The Government has certain rights in this invention.

### BACKGROUND

The Internet has witnessed tremendous growth over the past two decades, both in terms of user traffic and core link capacities. Currently, Internet (IP) traffic is already in the exabytes, and projections show global IP traffic will reach zettabytes in the next five years or so. This has led to a significant increase in the power/energy requirements of the associated networking infrastructure. Despite the fact that the majority of the power consumed is in home area networks and consumer devices, the density of power consumption is highest at core routers that are being scaled to switch terabits-per-second of bandwidth to support the increased traffic demand.

As router line card rates continue to increase, the limits of semiconductor (SRAM and DRAM) technology are being reached in terms of switching speeds, power savings and heat dissipation. Packet buffers used extensively in today's high-speed line cards are an integral part of every router (or switch) as they absorb transient bursts of traffic, and thus play a fundamental role in keeping packet loss to a minimum. On the downside, packet buffers introduce delay and jitter, and are largely responsible for the high cost, power consumption and heat dissipation in core routers. This observation has forced high capacity router/switch designers, and network providers to consider leveraging the use of optics for switching and transmission in core routers. For example, recent developments in this technology sector has produced working prototypes of all-optical packet switched routers. These optical routers employ integrated optical buffers. However, incorporating even a few packets of buffering using an all-optical on-chip memory is a formidable challenge due to the inherent complexity associated with maintaining the quality of the optical signal and the physical size limitations of the chip.

The concern in a buffer-less network is that packet losses can be unacceptably high. Several conventional techniques can be applied to deal with these losses. Wavelength conversion and hybrid optical/electronic switching have been proposed for reducing loss. However, these conventional techniques are expensive and can contribute significantly to the cost of the optical switch. Traffic shaping/pacing at the electronic edge routers can make traffic entering the core smoother, potentially reducing loss. However, this conventional approach is effective for packet losses arising from bursty traffic, but does not address packet losses from random contention, which is more common in a buffer-less core network.

### SUMMARY

The present invention relates to a system and method for enabling a buffer-less or substantially buffer-less core network using a packet-level forward error correction (FEC) coding scheme.

According to an embodiment of the present invention, the system includes an ingress edge router configured to receive data packets destined to at least one egress edge router via an access link from an end-host. The ingress edge router is connected to the at least one egress edge router via a core network, where the core network is buffer-less or substantially buffer-less. Also, the ingress edge router is configured to apply a forward error correction (FEC) encoding scheme to the data packets at a packet level and transmit the encoded data packets to the core network.

Also, the ingress edge router is configured to classify the data packets on an edge-to-edge basis, and apply the FEC encoding scheme per egress edge router. The core network may include at least one optical core router.

The ingress edge router computes a FEC packet for a block of data packets, and inserts and transmits the FEC packet to the core network before or after the block of data packets is transmitted. A block size of the block corresponds to a number of data packets included in the block. A size of the FEC packet may correspond to a maximum transmission unit (MTU) of the core network. The ingress edge router may compute the FEC packet based on header information and payload information of the data packets in the block.

According to an embodiment of the present invention, the FEC encoding scheme uses an exclusive or (XOR) scheme. In one particular embodiment, the block size is 3, 4 or 5.

According an embodiment of the present invention, the system may include an egress edge router configured to receive at least one block of encoded data packets from at least one ingress edge router via a core network. The egress edge router is connected to the at least one ingress edge router via the core network, where the core network is buffer-less or substantially buffer-less. The egress edge router is configured to receive at least one forward error correction (FEC) packet corresponding to a block of encoded data packets, and recover at least one lost data packet in the block using the at least one FEC packet, if the edge router detects at least one data packet as being lost. The core network may include at least one optical core router.

The egress router may receive the at least one FEC packet before or after the block of encoded data packets is received. A block size of the block may correspond to a number of data packets included in the block. In one particular embodiment, the block size is 3, 4 or 5. Also, a size of a FEC packet may correspond to a maximum transmission unit (MTU) of the core network.

According to an embodiment of the present invention, the system includes a core network, where the core network is buffer-less or substantially buffer-less. Also, the system includes a plurality of ingress edge routers. Each ingress edge router is configured to receive data packets via at least one access link from at least one end-host. Each ingress edge router is configured to apply a forward error correction (FEC) encoding scheme to the data packets at a packet level. Also, the system includes a plurality of egress edge routers. Each egress edge router is configured to receive a block of encoded data packets from the plurality of ingress edge routers via the core network. each egress edge router is configured to recover at least one lost data packet using a FEC decoding scheme.

Each ingress edge router is configured to classify the data packets on an edge-to-edge basis, and apply the FEC encoding scheme per egress edge router. In one embodiment, the FEC encoding scheme uses an exclusive or (XOR) scheme.

Each ingress edge router may compute a FEC packet for a block of data packets, and insert and transmit the FEC packet to the core network before or after the block of data packets is transmitted. A block size of the block may correspond to a number of data packets included in the block. In one embodiment, the block size is 3, 4 or 5.

Also, each egress edge router is configured to recover at least one lost data packet in the block using at least one FEC packet, if the edge router detects at least one data packet as being lost.

Embodiments of the present invention also provide a method for enabling a buffer-less or substantially buffer-less core network. The method includes receiving, by an ingress edge router, data packets destined to at least one egress edge router via an access link from an end-host, applying, by the ingress edge router, a forward error correction (FEC) encoding scheme to the data packets at a packet level, and transmitting, by the ingress edge router, the encoded data packets to the core network.

The method may further include classifying, by the ingress edge router, the data packets on an edge-to-edge basis, where the applying step applies the FEC encoding scheme per egress edge router. The method may further include computing, by the ingress edge router, a FEC packet for a block of data packets, where the transmitting step inserts and transmits the FEC packet to the core network before or after the block of data packets is transmitted. A block size of the block may correspond to a number of data packets included in the block.

The method may further include receiving, by an egress router, at least one block of the encoded data packets and the FEC packet corresponding to the at least one block from the ingress edge router via the core network, and recovering, by the egress edge router, at least one lost data packet in the block using the FEC packet, if the edge router detects at least one data packet as being lost.

### BRIEF DESCRIPTION OF THE DRAWINGS

Example embodiments will become more fully understood from the detailed description given herein below and the accompanying drawings, wherein like elements are represented by like reference numerals, which are given by way of illustration only and thus are not limiting of the present invention, and wherein:

FIG. 1 illustrates a system for enabling a buffer-less or substantially buffer-less core network according to embodiments of the present invention;

FIG. 2 illustrates a simulation screen shot of the edge-to-edge FEC framework of FIG. 1 using a single core-link dumbbell topology according to an embodiment of the present invention; and

FIG. 3 illustrates a graphic showing the results of the simulation shown in FIG. 2 according to an embodiment of the present invention.

### DETAILED DESCRIPTION OF EXAMPLE EMBODIMENTS

Various example embodiments of the present invention will now be described more fully with reference to the accompanying drawings in which some example embodiments of the invention are shown. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It should also be noted that in some alternative implementations, the functions/acts noted may occur out of the order noted in the figures. For example, two figures shown in succession may in fact be executed concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

In the following description, illustrative embodiments will be described with reference to acts and symbolic representations of operations (e.g., in the form of flowcharts) that may be implemented as program modules or functional processes include routines, programs, objects, components, data structures, etc., that perform particular tasks or implement particular abstract data types and may be implemented using existing hardware at existing network elements. Such existing hardware may include one or more Central Processing Units (CPUs), digital signal processors (DSPs), application-specific-integrated-circuits, field programmable gate arrays (FPGAs) computers or the like.

It should be borne in mind, however, that all of these and similar terms are to be associated with the appropriate physical quantities and are merely convenient labels applied to these quantities. Unless specifically stated otherwise, or as is apparent from the discussion, terms such as “acquiring” or “determining” or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

Embodiments of the present invention provide a system that enables a buffer-less or substantially buffer-less core network capable of delivering acceptable end-to-end performance. For instance, embodiments of the present application use a forward error correction (FEC) coding scheme at the packet level on an edge-to-edge basis to ensure an acceptable quality of performance in order to guard against packet loss suffered in the buffer-less or substantially buffer-less core network.

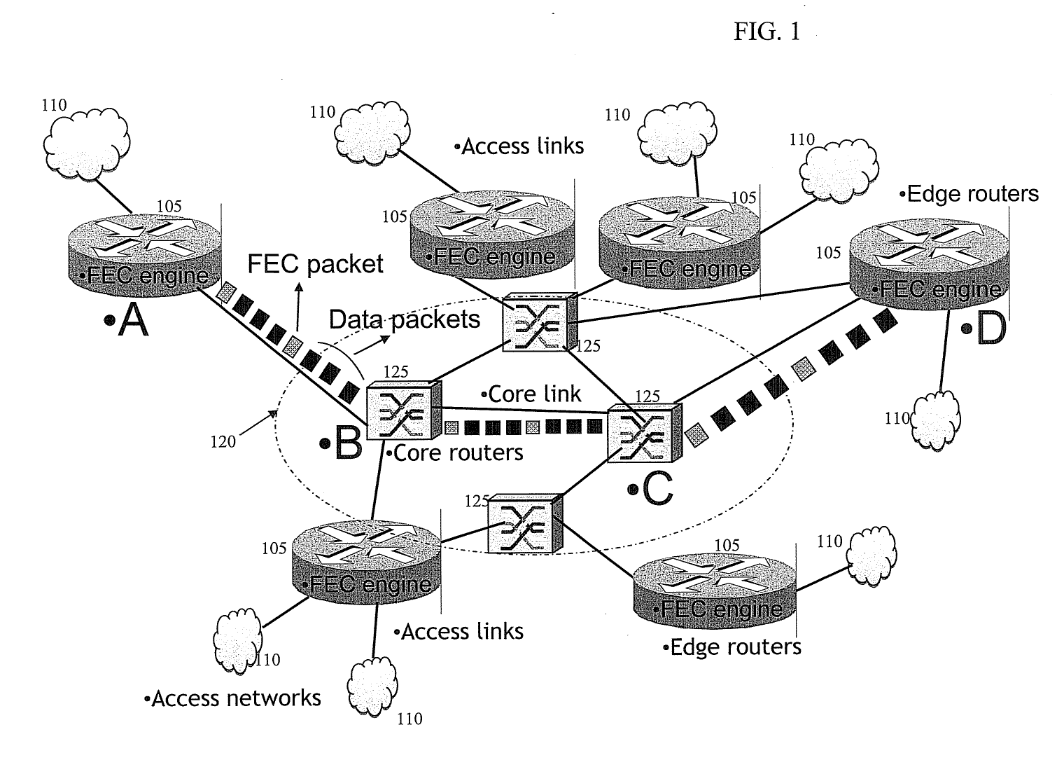

FIG. 1 illustrates a system for enabling a buffer-less or substantially buffer-less core network according to embodiments of the present invention. The system includes a plurality of edge routers 105, a plurality of access networks 110, and a core network 120 including core routers 125. Each edge router 105 is connected to at least one access network 110. The access network 110 may include portions of any type of standard communication network for providing access points to the internet such as IP aggregation routers, and/or Ethernet switches, for example. Each access point is connected to the edge router 105 via an access link, where each access link serves any number of end-hosts (not shown). As such, each edge router 105 is configured to receive data packets from end-hosts via the access links destined to other end-hosts in the same edge router 105 or a different edge router 105.

Data traffic from one edge router 105 destined to another edge router 105 is transmitted through the core network 120. The communication links between each of the edge routers 105 and the core network 120 may be referred to as edge router links. The edge router links may be electronic or optical. Data traffic may be communicated between each of the edge routers 105 and the core network 120 via the edge router links. The core network 120 includes at least one core router 125, as well as any other component well known in the art such as optical or electronic switches, for example. The communication links between the core routers 125 may be referred to as core router links. The core router links may be electronic or optical. The edge router links have relatively large buffers, and the core router links are buffer-less or substantially buffer-less. As such, the core network 120 is considered buffer-less or substantially buffer-less. Each edge router 105 is connected to another edge router 105 via the core network 120.

An ingress edge router is referred to as an edge router 105 that receives data packets destined to another edge router 105 via the access links from the end-hosts, and an egress edge router is referred to as an edge router 105 that receives data packets from another edge router 105 via the core network 120. At any particular moment, each edge router 105 may operate as an egress edge router or an ingress edge router, or both. The communication flow between one ingress edge router to one egress edge router may be referred as an edge-to-edge communication flow (e.g., A-B-C-D). If the system has N edge routers 105, the system contains N(N−1) edge-to-edge communication flows.

According to an embodiment of the present invention, the ingress edge router is configured to apply a forward error correction (FEC) encoding scheme to the data packets destined to another edge router (e.g., egress edge router) at the packet level, and transmit the encoded data packets to the core network 120. For example, when the ingress edge router receives the data packets from the end-hosts via the access links, the ingress edge router classifies the data packets on an edge-to-edge basis. For instance, the ingress edge router classifies the received data packets as being destined to a particular egress edge router. The ingress edge router makes this classification for each egress edge router that receive the data packets. Then, the ingress edge router applies the FEC encoding scheme to the classified data packets for each destination egress edge router.

The encoding scheme computes FEC packets for each edge-to-edge communication flow indicated by the received data packets, and inserts these computed FEC packets in the data traffic to be transmitted to the core network 120. For instance, if the system includes N edge routers 105, each edge router 105 computes the FEC packets for N−1 edge-to-edge communication flows. At each egress edge router, the edge router 105 recovers lost data packets using an FEC decoding scheme in the same manner that was applied at the encoder. Embodiments of the present invention encompass all types and strengths of an FEC coding scheme that are well-known in the art. For example, the FEC coding scheme may include any type of Fountain codes or block codes, or any type of FEC coding scheme that is well known in the art. The implementation of this FEC coding scheme on an edge-to-edge basis allows the end-hosts to be transparent, while maintaining control with the core network service provider (ISP).

For example, the ingress edge router computes a FEC packet for a block of received data packets, and inserts and transmits the FEC packet to the core network 120 before or after the block of data packets is transmitted. A block size of the block corresponds to a number of data packets included in the block. In the particular example in FIG. 1, the block size (also referred to as block strength) is 3. Therefore, after every third packet, the FEC packet is transmitted. Although FIG. 1 illustrates a block size of 3, embodiments of the present invention encompass any size of block. Also, the ingress edge router computes the FEC packet based on header information and payload information of the data packets in the block to ensure that the reconstructed data packets will be the same as the original (missing) data packet on a bit level basis. A size of the FEC packet may correspond to a maximum transmission unit (MTU) of the core network 120.

In one particular example of an FEC coding scheme, the ingress edge router uses an exclusive or (XOR) scheme for the FEC coding scheme. In the XOR scheme, the ingress edge router computes the FEC packet as including an XOR value. The XOR value indicates that the packet is an FEC packet.

The egress edge router is configured to receive the block of data packets and the FEC packet(s) corresponding to the block of data packets, and recover lost data packets in the block using the FEC packet(s), if the egress edge router detects at least one data packet as being lost. In the XOR scheme, the egress edge router maintains a running XOR of the received packets, which are received from the ingress edge router. If the egress edge router detects at least one lost data packet in the window of K+1 received packets (K being the size of the block), the FEC packet is used to recover the lost data packet, which is then forwarded on to the access links.

Next, the performance of the system using the XOR scheme is simulated using dumbbell topology.

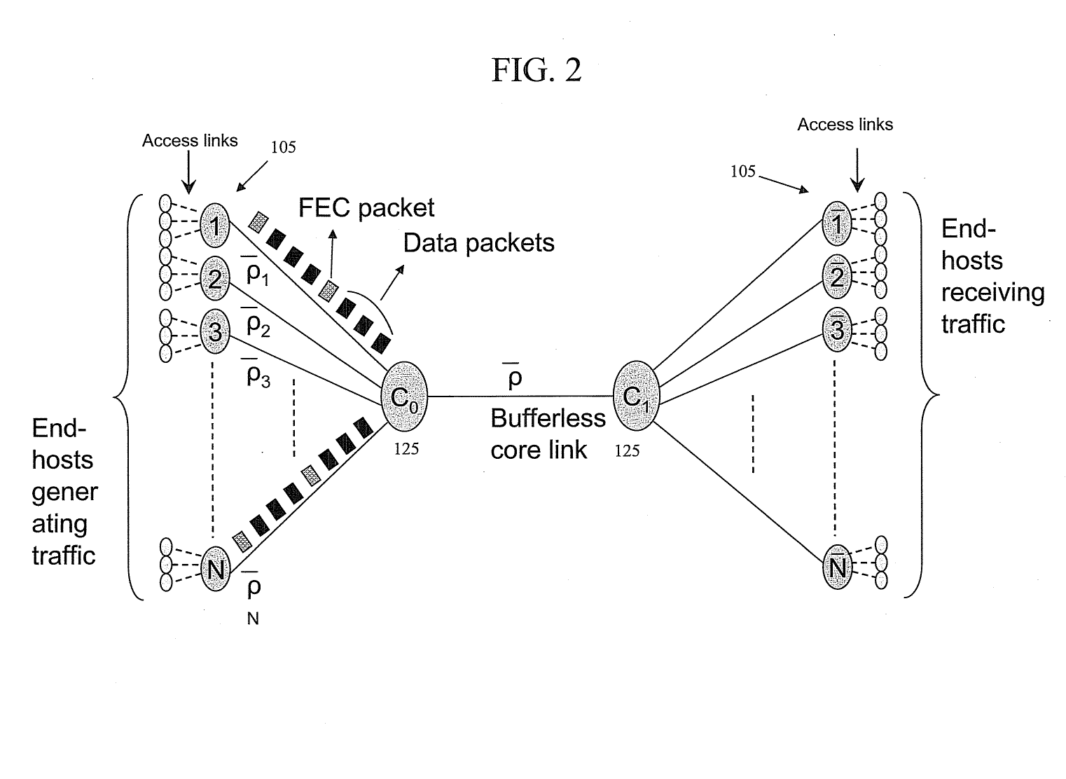

FIG. 2 illustrates a simulation screen shot of the edge-to-edge FEC framework of FIG. 1 using a single core-link dumbbell topology according to an embodiment of the present invention. For example, the edge-to-edge FEC framework in FIG. 1 is simulated in a simulation program (ns-2) using the single core-link dumbbell topology shown in FIG. 2. The simulation uses a plurality of N ingress edge routers 105 and a plurality of N egress edge routers 105, two core routers 125, and a plurality of end-hosts connected to each ingress edge routers 105 and egress edge routers 105 via the access links.

In this particular simulation, the 10 edge router links transmit traffic into the bufferless core router link at core router Cₒ, with each edge router link receiving traffic from three access links. Each of the 30 end-hosts includes 5 TCP agents. Therefore, the network simulates 150 long-lived TCP flows. Similarly, the TCP flows are linked by the 30 end-hosts for the egress edge routers 105. The propagation delays on the access and edge router links are uniformly distributed between [1, 5] ms, while the core router link Cₒ-C₁ has a delay of 15 ms.

The TCP flows are bottlenecked at the access links, rather than the core network, which typically has a much higher capacity. The access link speeds are uniformly distributed in [2, 5] Mbps, all edge router links operate at 40 Mbps, and the core router link operates at 400 Mbps. For these link speeds, the access link is the bottleneck because each flow's fair-share of the bandwidth on the access links vary between 0.4-1 Mbps, while each flow's fair-share of the bandwidth on the edges and the core network 120 are 2.67 Mbps. The start time of the TCP flows is uniformly distributed in the interval [0, 10] sec and the simulation is performed for 35 sec.

The average per-flow TCP goodput is measured for each setting of the FEC block-size k in the simulation. Goodput is used as a metric because goodput is one of the more important measurements for end-users, who want their transactions to completed as fast as possible. It should be mentioned that simulation software ns-2 does not permit setting the buffer size to zero as the simulation software simulates store-and-forward rather than cut-through switches. Therefore, the simulation uses a buffer size of 1 KB (the closest the simulation program can come to zero buffer) to accommodate a single TCP packet that is stored and forwarded by the switch.

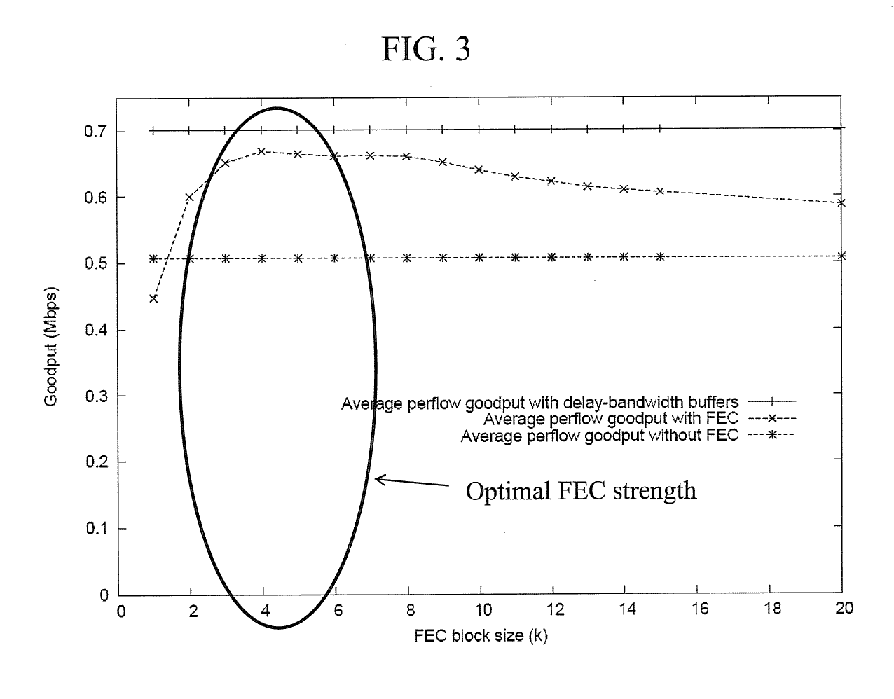

FIG. 3 illustrates a graphic showing the results of the simulation shown in FIG. 2 according to an embodiment of the present invention. For example, FIG. 3 shows the per-flow TCP goodput as a function of the block-size k. For comparison, FIG. 3 also depicts, via horizontal lines, the average goodput without FEC (the bottom line) and the average goodput if the core router link were to have sufficient (delay-bandwidth) buffering of around 12.5 MB (top line). Large buffers yield a per-flow goodput of 0.7 Mbps, while eliminating buffers reduces this goodput to 0.43 Mbps, a sacrifice in goodput of nearly 40%. However, employing edge-to-edge FEC over the bufferless link can improve per-flow goodput substantially, peaking at nearly 0.6 Mbps when the FEC block-size k is in the range of 3-5, and bringing the per-flow TCP goodput for the bufferless link to within 15% of a fully-buffered link.

Variations of the example embodiments of the present invention are not to be regarded as a departure from the spirit and scope of the example embodiments of the invention, and all such variations as would be apparent to one skilled in the art are intended to be included within the scope of this invention.

What is claimed:

1. A system for enabling a buffer-less or substantially buffer-less core network, comprising:
an ingress edge router configured to receive data packets destined to at least one egress edge router via an access link from an end-host, the ingress edge router being connected to the at least one egress edge router via a core network, the core network being buffer-less or substantially buffer-less; and
the ingress edge router configured to apply a forward error correction (FEC) encoding scheme to the data packets at a packet level and transmit the encoded data packets to the core network.

2. The system of claim 1, wherein the ingress edge router is configured to classify the data packets on an edge-to-edge basis, and apply the FEC encoding scheme per egress edge router.

3. The system of claim 1, wherein the core network includes at least one optical core router.

4. The system of claim 1, wherein the FEC encoding scheme uses an exclusive or (XOR) scheme.

5. The system of claim 1, wherein the ingress edge router computes a FEC packet for a block of data packets, and inserts and transmits the FEC packet to the core network before or after the block of data packets is transmitted, a block size of the block corresponds to a number of data packets included in the block.

6. The system of claim 5, wherein the ingress edge router computes the FEC packet based on header information and payload information of the data packets in the block.

7. The system of claim 5, wherein the block size is 3, 4 or 5.

8. A system for enabling a buffer-less or substantially buffer-less core network, comprising:
an egress edge router configured to receive at least one block of encoded data packets from at least one ingress edge router via a core network, the egress edge router being connected to the at least one ingress edge router via the core network, the core network being buffer-less or substantially buffer-less;
the egress edge router configured to receive at least one forward error correction (FEC) packet corresponding to a block of encoded data packets; and
the egress edge router configured to recover at least one lost data packet in the block using the at least one FEC packet, if the edge router detects at least one data packet as being lost.

9. The system of claim 8, wherein the core network includes at least one optical core router.

10. The system of claim 8, wherein a block size of the block corresponds to a number of data packets included in the block.

11. The system of claim 10, wherein the block size is 3, 4 or 5.

12. A system for enabling a buffer-less or substantially buffer-less core network, comprising:
a core network, the core network being buffer-less or substantially buffer-less;
a plurality of ingress edge routers, each ingress edge router being configured to receive data packets via at least one access link from at least one end-host, each ingress edge router configured to apply a forward error correction (FEC) encoding scheme to the data packets at a packet level; and
a plurality of egress edge routers, each egress edge router being configured to receive a block of encoded data packets from the plurality of ingress edge routers via the core network, each egress edge router being configured to recover at least one lost data packet using a FEC decoding scheme.

13. The system of claim 12, wherein each ingress edge router is configured to classify the data packets on an edge-to-edge basis, and apply the FEC encoding scheme per egress edge router.

14. The system of claim 12, wherein the FEC encoding scheme uses an exclusive or (XOR) scheme.

15. The system of claim 12, wherein each ingress edge router computes a FEC packet for a block of data packets, and inserts and transmits the FEC packet to the core network before or after the block of data packets is transmitted, a block size of the block corresponds to a number of data packets included in the block.

16. The system of claim 15, wherein the block size is 3, 4 or 5.

17. The system of claim 12, wherein each egress edge router is configured to recover at least one lost data packet in the block using at least one FEC packet, if the edge router detects at least one data packet as being lost.

18. A method for enabling a buffer-less or substantially buffer-less core network, comprising:
receiving, by an ingress edge router, data packets destined to at least one egress edge router via an access link from an end-host, the ingress edge router being connected to the at least one egress edge router via a core network, the core network being buffer-less or substantially buffer-less; and
applying, by the ingress edge router, a forward error correction (FEC) encoding scheme to the data packets at a packet level; and
transmitting, by the ingress edge router, the encoded data packets to the core network.

19. The method of claim 18, further comprising:
classifying, by the ingress edge router, the data packets on an edge-to-edge basis, wherein the applying step applies the FEC encoding scheme per egress edge router.

20. The method of claim 18, further comprising:
computing, by the ingress edge router, a FEC packet for a block of data packets, wherein the transmitting step inserts and transmits the FEC packet to the core network before or after the block of data packets is transmitted, a block size of the block corresponds to a number of data packets included in the block.

21. The method of claim 18, further comprising:
receiving, by an egress router, at least one block, of the encoded data packets and the FEC packet corresponding to the at least one block from the ingress edge router via the core network;
recovering, by the egress edge router, at least one lost data packet in the block using the FEC packet, if the edge router detects at least one data packet as being lost.
